(19) United States
(12) Patent Application Publication
(10) Pub. No.: US 2026/0181785 A1
(43) Pub. Date: Jun. 25, 2026

(54) Method for Manufacturing an Electronic Device and Optical Inspection System

(71) Applicant: InnoLux Corporation, Miao-Li County (TW)

(72) Inventors: Chin-Lung TING, Miao-Li County (TW); Kuang-Ming FAN, Miao-Li County (TW)

(73) Assignee: InnoLux Corporation, Miao-Li County (TW)

(21) Appl. No.: 19/401,406

(22) Filed: Nov. 26, 2025

Related U.S. Application Data
(60) Provisional application No. 63/737,800, filed on Dec. 23, 2024.

(30) Foreign Application Priority Data
Aug. 5, 2025 (CN) 202511089131.6

(51) Int. Cl. H05K 3/00; H05K 3/40

(52) U.S. Cl. CPC H05K 3/0026; H05K 3/4038; H05K 2203/107; H05K 2203/162; H05K 2203/163

(57) ABSTRACT

A method for manufacturing an electronic device includes providing substrate; performing first modification step on at least portion of substrate; generating first side-incident light to introduce first side-incident light into interior of substrate; inspecting substrate after first modification step to acquire detection information related to state of substrate; and based on detection information, determining whether rework process is required.

### CROSS REFERENCE TO RELATED APPLICATION

This application claims the benefit of U.S. Provisional Application No. 63/737,800, filed on Dec. 23, 2024. The content of the application is incorporated herein by reference.

### BACKGROUND OF THE DISCLOSURE

### 1. Field of the Disclosure

The present disclosure relates to a method for manufacturing an electronic device and an optical inspection system, and more particularly, to a method for manufacturing an electronic device and an optical inspection system that supports a transparent substrate.

### 2. Description of the Prior Art

Laser modification technology is commonly utilized to form Through Glass Vias (TGVs) on a glass substrate. The quality of this process is related to the reliability of subsequent processes and the final product, and therefore requires strict inspection. Relying solely on top-view Automated Optical Inspection (AOI) to observe surface morphology may be insufficient for determining the risks posed by potential micro-cracks or other defects within the internally modified regions of a transparent substrate. Therefore, providing an efficient inspection method for transparent substrates is an issue that needs to be addressed.

### SUMMARY OF THE DISCLOSURE

In one embodiment, a method for manufacturing an electronic device is disclosed. The method comprises providing a substrate; performing a first modification step on at least a portion of the substrate; generating a first side-incident light to introduce the first side-incident light into an interior of the substrate; inspecting the substrate after the first modification step to acquire detection information related to a state of the substrate; and based on the detection information, determining whether a rework process is required for the substrate.

In another embodiment, an optical inspection system is disclosed. The optical inspection system comprises an object to be measured, a first light source disposed at a side of the object to be measured and configured to provide a first side-incident light, and a lens disposed above the object to be measured. After a first modification step is performed on at least a portion of the object to be measured, the first light source generates the first side-incident light to introduce the first side-incident light into an interior of the object to be measured. The lens inspects an image of the object to be measured after the first modification step. The image is formed on a photosensitive element, to acquire detection information related to a state of the object to be measured. The detection information is used for determining whether a rework process is required for the object to be measured.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a flowchart of a method for manufacturing an electronic device according to an embodiment of the present disclosure.

FIG. 2 is a schematic diagram illustrating a laser modification step in the method for manufacturing the electronic device of FIG. 1.

FIG. 3 is a schematic diagram illustrating an etching step in the method for manufacturing the electronic device of FIG. 1.

FIG. 4 is a schematic diagram illustrating detecting a contour of a laser-modified region and a scratch on a substrate by utilizing a first side-incident light, in the method for manufacturing the electronic device of FIG. 1.

FIG. 5 is a schematic diagram illustrating detecting a through-hole region and a defect on the substrate by utilizing the first side-incident light, in the method for manufacturing the electronic device of FIG. 1.

FIG. 6 is a block diagram of an optical inspection system according to a first embodiment of the present disclosure.

FIG. 7 is a block diagram of an optical inspection system according to a second embodiment of the present disclosure.

FIG. 8 is a block diagram of an optical inspection system according to a third embodiment of the present disclosure.

FIG. 9 is a structural diagram of an electronic device according to an embodiment of the present disclosure.

FIG. 10 is a structural diagram of an electronic device according to another embodiment of the present disclosure.

### DETAILED DESCRIPTION

The present disclosure can be understood by referring to the following detailed description and the accompanying drawings. It is noted that, for the convenience of the reader and the simplicity of the drawings, a plurality of drawings in the present disclosure only depict a portion of an electronic device, and specific components in the drawings are not drawn to actual scale. Furthermore, the quantity and dimensions of each component in the drawings are only for illustrative purposes and are not intended to limit the scope of the present disclosure.

Certain terms are used throughout the specification and the appended claims of the present disclosure to refer to particular components. Those skilled in the art should understand that manufacturers of electronic equipment may refer to the same component by different names. This document does not intend to distinguish between components that have the same function but different names.

In the following specification and claims, the terms “includes”, “including”, “has”, “having”, and the like are open-ended terms and, therefore, should be interpreted as “including but not limited to . . . ”. Therefore, when the terms “includes”, “including”, and/or “having” are used in the description of the present disclosure, they specify the presence of the corresponding features, regions, steps, operations, and/or components, but do not preclude the presence of one or more other corresponding features, regions, steps, operations, and/or components.

The directional terms mentioned herein, such as “up”, “down”, “front”, “back”, “left”, “right”, and the like, are only for reference to the orientation of the drawings. Therefore, the directional terms used are for illustrative purposes and are not intended to limit the present disclosure. In the drawings, each figure illustrates general features of the method, structure, and/or materials used in a particular embodiment. However, these drawings should not be construed as defining or limiting the scope or nature covered by these embodiments. For example, the relative dimensions, thicknesses, and positions of various layers, regions, and/or structures may be reduced or exaggerated for the sake of clarity.

When a corresponding component (e.g., a layer or region) is referred to as being “on” another component, it can be directly on the other component, or intervening components may be present between them. On the other hand, when a component is referred to as being “directly on” another component, there are no intervening components present. In addition, when a component is referred to as being “on” another component, there is a vertical relationship between the two, and the component can be above or below the other component, wherein this up-down relationship depends on the orientation of the device.

It should be understood that when a component or layer is referred to as being “connected to” another component or layer, it can be directly connected to the other component or layer, or intervening components or layers may be present. When a component is referred to as being “directly connected to” another component or layer, there are no intervening components or layers present. In addition, when a component is referred to as being “coupled to another component (or variations thereof)”, it can be directly electrically connected to the other component, or indirectly connected (e.g., indirectly electrically connected) to the other component through one or more components.

In the present disclosure, when a component is “disconnected” from another component, an electrical signal cannot flow between the two components within a specified time.

The terms “approximate” or “about” are generally interpreted to be within a range of ±10% of a given value, or interpreted to be within a range of ±5%, ±3%, ±2%, ±1%, or ±0.5% of the given value.

Ordinal numbers such as “first”, “second”, and the like, used in the specification and claims to modify components, do not in themselves imply or represent that the component(s) have any preceding ordinal number, nor do they represent an order of one component relative to another, or an order in a manufacturing method. The use of these ordinal numbers is only to clearly distinguish a component having a certain name from another component having the same name. The claims and the specification may not use the same terms. Accordingly, a first component in the specification may be a second component in the claims.

It should be understood that features from several different embodiments described below can be replaced, recombined, and mixed to form other embodiments without departing from the spirit of the present disclosure. Features between embodiments can be arbitrarily mixed and matched as long as they do not contradict the spirit of the invention or conflict with each other.

In the present disclosure, an electronic device can include a power module, a semiconductor device, a display device, a light-emitting device, an antenna device, a sensing device, a medical device, a splicing device, or any combination thereof, but is not limited thereto. The display device can be a non-self-emitting display or a self-emitting display according to requirements. The antenna device can be a liquid-crystal type antenna device or a non-liquid-crystal type antenna device. The sensing device can be a sensing device for sensing capacitance, light, thermal energy, or ultrasound. The medical device can be a medical detection device. The splicing device can be a display splicing device or an antenna splicing device, but is not limited thereto. The electronic device can include electronic components, which can include passive components and active components, such as a capacitor, a resistor, an inductor, a diode, an electrowetting element, a switching element, a die, a chip, a High Bandwidth Memory (HBM), or can refer to electronic components that include a semiconductor layer or are fabricated through a semiconductor process. The diode can be a die or a chip, and can include a light-emitting diode (LED), a photodiode, or a varactor, but is not limited thereto. The switching element can be a transistor, and the transistor can include, for example, a top-gate thin-film transistor, a bottom-gate thin-film transistor, or a dual-gate thin-film transistor, but is not limited thereto. The electronic device can have peripheral systems such as a driving system, a control system, a light source system, and the like to support the components within the electronic device.

It should be noted that technical features in the different embodiments described below can be replaced, recombined, or mixed with each other to form another embodiment without departing from the spirit of the present disclosure.

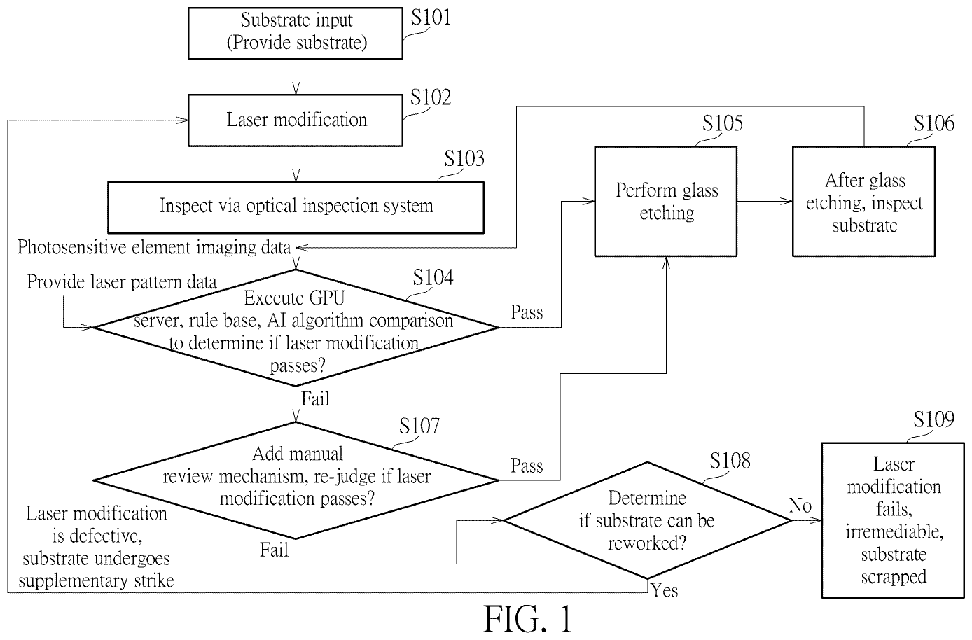

FIG. 1 is a flowchart of a method for manufacturing an electronic device according to an embodiment of the present disclosure. The method for manufacturing the electronic device disclosed in the embodiment further utilizes a side-incident light technology to improve the detection of the condition of a substrate before and after an internal modification. By performing real-time, non-destructive internal and surface inspection before etching and by combining the inspection with an artificial intelligence algorithm for precise analysis and comparison, a plurality of defects such as scratches, cracks, roughness, and a pitch between through-holes can be effectively identified. The method of the embodiment not only enables real-time determination of whether a rework is required but also allows for corresponding adjustment of laser parameters, significantly improving yield and efficiency. Therefore, the method can be widely applied to quality monitoring in high-precision laser micro-machining processes for transparent substrates, such as for Through Glass Vias (TGVs), advanced packaging, and display panels, and particularly provides a more reliable and cost-effective solution for the processing of transparent substrates such as glass. As illustrated in FIG. 1, the flow of the method for manufacturing the electronic device can include steps S101 to S109. Any reasonable technical modifications or hardware replacements fall within the scope of the present disclosure. Steps S101 to S109 are described as follows:
Step S101: providing a substrate;
Step S102: performing laser modification;
Step S103: inspecting the substrate through an optical inspection system;
Step S104: performing a comparison by a Graphics Processing Unit (GPU) server, a rule base, and an artificial intelligence (AI) algorithm to determine whether the laser modification passes? If yes, proceed to step S105; if no, proceed to step S107;
Step S105: performing glass etching;
Step S106: after the glass etching, inspecting the substrate, and again inputting photosensitive element data into a processing unit to match its etching similarity;
Step S107: adding a manual review mechanism to re-judge whether the laser modification passes? If yes, proceed to the glass etching of step S105; if no, proceed to step S108;
Step S108: determining whether the substrate can undergo a rework process? If yes, return to step S102, which indicates a defect in the laser modification, and the substrate undergoes a supplementary strike; if no, proceed to step S109;
Step S109: the laser modification fails, cannot be remedied, and the substrate is scrapped.

In step S101, a substrate to be processed can be provided. The substrate can be a glass substrate, a sapphire substrate, a quartz substrate, a silicon substrate, or another transparent or semi-transparent substrate suitable for a semiconductor process or a display process. In the present embodiment, a glass substrate is a preferred example. The dimensions and thickness of the substrate can be determined based on actual product requirements. In some embodiments, before performing a subsequent laser modification, a protective layer (described later) can be disposed on a side of the substrate (e.g., a side opposite to the laser incidence). The protective layer can be an adhesive tape, another piece of glass, a Printed Circuit Board (PCB), a Bismaleimide-Triazine (BT) material, or FR-4 (Flame Retardant 4), and the main purpose of the protective layer is to protect the substrate surface, reduce debris generation, or assist laser energy absorption during the laser modification process. Furthermore, depending on process requirements, the substrate may also undergo a substrate thinning step at this stage or earlier to prepare the substrate for being sent into a processing or inspection apparatus.

In step S102, a first modification step can be performed on at least a portion of the substrate. In the present embodiment, the first modification step can be a laser modification. The laser modification can utilize a laser beam emitted from a laser source to irradiate specific regions of the substrate to change the material properties of these regions, thereby forming a plurality of laser-modified regions. These laser-modified regions are usually for pre-defining paths for a subsequent etching step, making the laser-modified regions easier to be removed by an etchant.

After the laser modification of step S102 is completed, but before the etching of step S105 is performed, the optical inspection system proposed in the present disclosure can perform a non-destructive optical inspection on the substrate according to step S103. This step is one of the key steps of the present disclosure, and the purpose of this step is to evaluate the quality of the laser modification in real time. The principle of step S103 is to utilize a side-incident light to probe an interior of the substrate (especially a transparent or semi-transparent substrate) to acquire state information of the laser-modified regions and the entire substrate. Furthermore, a second side-incident light can also be provided from another side of the substrate to acquire richer information.

When the first side-incident light propagates inside the substrate, its optical properties (such as intensity, direction, phase, etc.) will change due to interaction (such as scattering, refraction, reflection, or absorption) with the laser-modified regions and possibly existing defects (such as scratches, cracks, micro-pimples, or dimples), which will also cause identifiable optical changes. Moreover, the contour or dimensions (such as an inner aperture and an outer aperture) of the laser-modified regions will also affect the propagation result of the light.

The system captures the output light after the interaction through a lens and a camera (which can include a photosensitive element) from above the substrate or another suitable position, and converts the output light into an image (referred to herein as: photosensitive element imaging data). The photosensitive element imaging data contains rich detection information related to the state of the substrate. To achieve a comprehensive inspection, this inspection step can be designed to be performed sequentially on a plurality of regions of the substrate, so that a subsequent overall evaluation (such as generating an inspection map) can be performed smoothly. The details will be described later.

In step S104, the method for manufacturing the electronic device can perform a comparison by the GPU server, the rule base, and the AI algorithm to determine whether the laser modification passes. In this step, the acquired detection information (i.e., the photosensitive element imaging data) is transmitted to a processing unit (the present disclosure may refer to any computing mechanism such as a GPU server, a cloud processor, an AI accelerator, etc., collectively as a processing unit). The processing unit can read a pre-stored rule base or reference laser pattern data from a memory. Then, the processing unit can execute the AI algorithm. The AI algorithm performs an in-depth analysis and comparison on the received detection information. For example, this analysis can include but is not limited to: (a) comparing the real-time image with the reference laser pattern data to determine whether a morphology of the modified regions meets expectations; (b) detecting whether scratches or cracks exist on the substrate; (c) evaluating a surface roughness of the substrate; and (d) measuring a pitch between two adjacent through-hole regions and determining whether the pitch conforms to a preset standard. Based on the comparison and analysis result of the AI algorithm, the processing unit determines whether the current laser modification passes. If the determination result is “pass”, the flow proceeds to step S105; if the determination result is “fail”, the flow proceeds to step S107.

In step S105, if the substrate passes the AI determination, indicating that the laser modification quality meets requirements, a subsequent process can be performed. In the present embodiment, the subsequent process is performing a glass etching step. Before this step, if a protective layer was previously disposed, a step of removing the protective layer needs to be performed first. Then, the substrate is etched using an etchant (wet or dry). Since the material properties of the laser-modified regions have been changed, the etchant will preferentially etch along these regions, finally forming the required through-holes.

After the etching is completed, in step S106, the substrate can be optionally inspected again. The purpose of this inspection can be to confirm whether the through-holes have been properly formed, whether the aperture meets specifications, or to check if new defects were introduced during the etching process. This step can also include inputting the photosensitive element data into the processing unit again for comparison of post-etching morphology or for similarity matching, as a final quality confirmation.

If in step S104, the AI algorithm determines that the laser modification “fails”, the flow proceeds to step S107. To avoid possible misjudgments by the AI or to handle edge cases, step S107 introduces a manual review mechanism. An operator or an engineer reviews the substrate that failed the AI determination and its related detection information (such as images, AI analysis data, etc.), and performs a re-judgment based on experience and standards. If the manual re-judgment deems that the substrate quality is actually acceptable, or that the AI determination was too strict or incorrect, the determination result can be corrected to “pass”, and the flow proceeds to step S105 for etching. If the manual re-judgment confirms that there is indeed a problem with the laser modification, the determination result is maintained as “fail”, and the flow proceeds to step S108.

If the substrate is confirmed as failed in step S107, then in step S108, it is determined whether the defect can be remedied through a rework process. This depends on the type and severity of the defect, as well as the feasibility of the process. If the determination is “yes” (rework is possible), it indicates that the laser modification parameters may have been slightly off, there may be local defects, or a missed shot, and a supplementary strike or another modification can be performed. At this point, the flow returns to step S102 to perform a “laser re-modification step”. It should be understood that the first modification step is performed utilizing a first laser condition. The laser re-modification step is performed utilizing a second laser condition. Furthermore, the second laser condition can be different from the first laser condition. For example, the first laser condition includes but is not limited to a femtosecond laser, a wavelength of 1030 nanometers (nm), a pulse energy of 1.5 microjoules (μJ), a repetition rate of 500 kilohertz (kHz), and a scanning speed of 250 millimeters per second (mm/s), and adopts a fast dot matrix scan or a large-area spiral scan. The first laser condition is for maximizing production efficiency while maintaining a certain level of quality.

After inspection, the system may find that among a plurality of modified spots, some spots have insufficient modification depth due to minor non-uniformity of the substrate material or instantaneous fluctuations in the laser output, or some spots were “missed shots” because the laser beam was blocked by micro-dust. These are determined as “defects in laser modification” and are determined to be reworkable in step S108. Therefore, the second laser condition can be set to include but is not limited to a femtosecond laser with a wavelength of 1030 nm. For spots with insufficient depth, the pulse energy may be reduced to 0.8 μJ, but the number of pulses applied to the spot may be increased (e.g., by reducing the scanning speed or repeatedly irradiating the spot) to more finely control energy deposition and deepen the modification layer by layer, avoiding over-modification. For “missed shots”, a pulse energy similar to the first laser condition (1.5 μJ) may be used, but only for irradiating that single spot. The repetition rate may be maintained at 500 kHz or adjusted according to the required number of pulses. For spots that need reinforcement, the scanning speed would be significantly reduced, or a precise single-spot dwelling irradiation would be used instead. Furthermore, the scanning strategy is no longer a large-area scan, but high-precision point-to-point positioning and targeted irradiation. In other words, when performing the laser re-modification, a “second laser condition” different from the first laser condition may be used, for example, by adjusting laser parameters, to correct the defects. If the determination is “no” (rework is not possible), the flow proceeds to step S109.

In step S109, if the defect of the substrate is determined to be irremediable through rework, it indicates that the current laser modification has failed. The substrate will be deemed a scrapped product and removed from the production line to avoid wasting resources in subsequent processes.

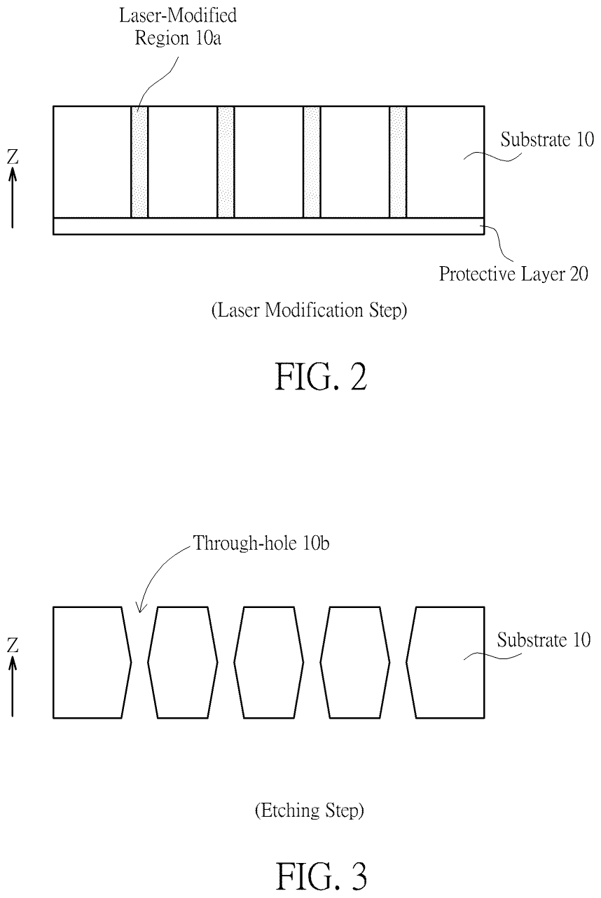

FIG. 2 is a schematic diagram illustrating a laser modification step in the method for manufacturing the electronic device. FIG. 3 is a schematic diagram illustrating an etching step in the method for manufacturing the electronic device. To enable a person of ordinary skill in the art to easily understand the disclosed content, the following will describe the details of the manufacturing steps of a Through Glass Via (TGV), including pre-processing steps. First, a substrate input (Substrate In) is performed. This step corresponds to step S101 described previously, wherein a substrate to be processed is provided. The substrate is typically a transparent or semi-transparent material such as glass. Next, before performing the main laser modification step, the embodiment further includes providing a protective layer on a side of the substrate. The main purpose of providing the protective layer is to reduce defects that may be generated in subsequent processes. The protective layer can be bonded to or cover the top of or a side of the substrate. According to some embodiments, the protective layer can be omitted.

Next, a substrate thinning step is performed. In some embodiments, after the protective layer 20 is provided, or as part of the pre-processing of the substrate 10, a thinning process may be performed on the substrate 10. The purpose of the thinning process is to adjust the substrate 10 to a specific thickness required for the final product. The thinning process can be performed by grinding, polishing, or chemical etching, to prepare for the subsequent laser modification. Next, a laser modification step is performed. Referring to FIG. 2, the laser modification step corresponds to the first modification step described in the previous flowchart S102. In this stage, a laser source can be utilized to irradiate the substrate 10 covered with the protective layer 20 to form laser-modified regions 10a inside the substrate 10. It should be understood that the protective layer 20 can protect the surface of the substrate 10 from thermal damage or debris contamination that may be caused by direct laser irradiation in this step, thereby suppressing the generation of surface defects. A laser beam will penetrate the substrate 10 to form the intended laser-modified regions 10a. The laser-modified regions 10a are preset paths for the subsequent etching to form through-holes.

Next, a step of removing the protective layer is performed. After the laser modification step is completed, the protective layer 20 that originally covered the substrate 10 needs to be removed. The removal method can be determined according to the material properties of the protective layer 20. For example, the removal can be performed by ultraviolet (UV) irradiation, heating, or any other suitable method. The protective layer 20 has been removed from the substrate 10, thereby exposing the laser-modified substrate 10 and the laser-modified regions 10a inside the substrate 10. The step of removing the protective layer can ensure that the subsequent etching process can directly act on the laser-modified regions 10a. Next, an etching step is performed to form through-holes. Referring to FIG. 3, after the protective layer 20 is removed, an etching step is performed on the substrate 10. This step corresponds to step S105 described in the previous flowchart. A suitable etchant (wet or dry) is utilized to selectively remove the laser-modified regions 10a, thereby forming through-holes 10b in the substrate 10. Because the material properties of the laser-modified regions 10a have been changed, their etching rate is much higher than that of the unmodified substrate material, so that the through-holes 10b with a desired aspect ratio can be accurately formed.

It should be understood that during the processing of the glass substrate, particularly without adequate protection, a plurality of surface defects may be generated. The protective layer 20 in the embodiment helps to suppress the generation of these defects. However, these defect types may include: bubbles, dimples, pimples, and scratches. A bubble may be caused by gas generated inside the material or attached to the surface during the process. A dimple is a tiny depression on the surface of the substrate. A pimple is a tiny protrusion on the surface of the substrate. A scratch is a line-shaped damage on the surface of the substrate caused by a mechanical action. The inspection system and method of the present disclosure are capable of detecting these and other internal defects before etching, and determining whether a rework is required.

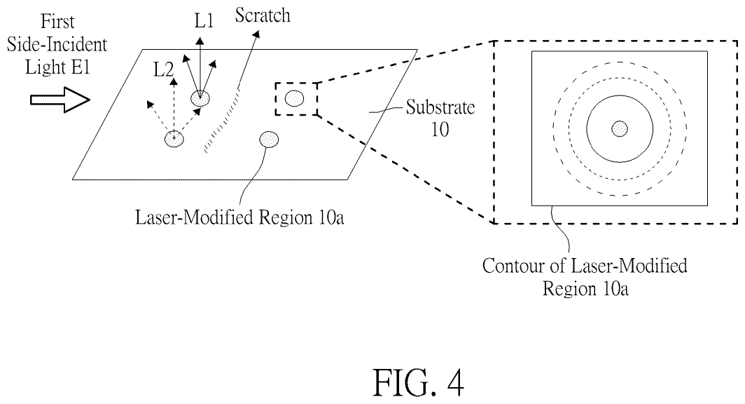

FIG. 4 is a schematic diagram illustrating the utilization of a first side-incident light E1 to detect a contour of a laser-modified region 10a and a scratch on a substrate, in the method for manufacturing the electronic device. FIG. 4 illustrates a partial principle of how an inspection system acquires detection information related to a state of a substrate in step S103. As illustrated in FIG. 4, when the first side-incident light E1 is introduced into an interior of the substrate 10 from a side of the substrate 10, the light propagates inside the substrate 10. If a scratch exists on a surface of or inside the substrate 10, when the first side-incident light E1 encounters the scratch, its propagation path changes significantly. A portion of the light may be scattered due to a rough surface or a cross-section of the scratch. For example, scattered light paths L1 and L2 are schematically depicted in FIG. 4. The scattered light may exit the substrate upwardly or in other directions and be captured by a photosensitive element within a lens 12 located above the substrate. Another portion of the light may be unable to penetrate along an expected path due to blockage or refraction by the scratch, or its intensity may be attenuated.

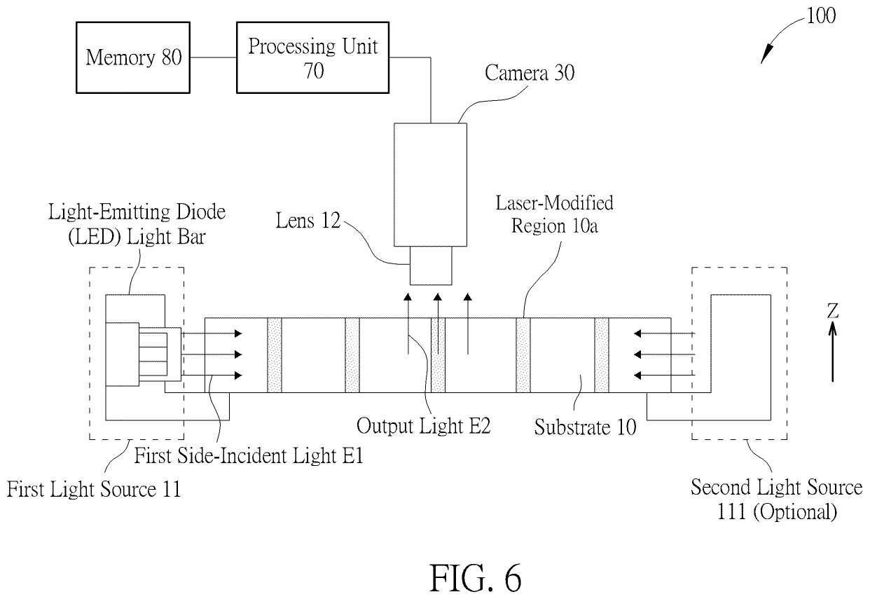

Furthermore, because the material properties of the laser-modified region 10a itself have been altered by a laser, its optical properties (such as refractive index, absorptivity) will be different from those of the surrounding unmodified substrate material. Therefore, when the first side-incident light E1 encounters a boundary or an interior of the laser-modified region 10a, refraction, reflection, or scattering will also occur. This allows the contour of the laser-modified region 10a to be highlighted. An enlarged view on a right side of FIG. 4 schematically illustrates the contour of the region after modification, the edge of which may form a specific optical contrast, facilitating identification and measurement by an inspection system. By analyzing a light distribution, an intensity variation, or a specific pattern formed that is received by the photosensitive element, a processing unit 70 (as illustrated in FIG. 6 to FIG. 8, not shown in FIG. 4) can determine whether the scratch exists, its position, and its approximate severity, and can also evaluate whether the contour of the laser-modified region 10a meets expectations.

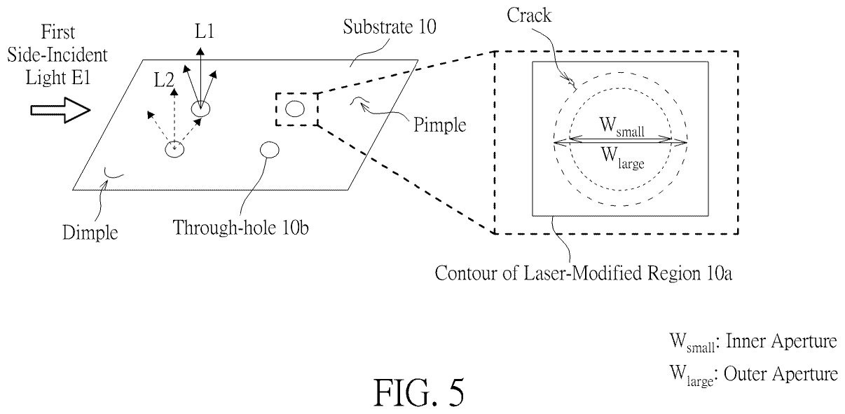

FIG. 5 is a schematic diagram illustrating the utilization of a first side-incident light to detect a through-hole region and a defect on a substrate, in the method for manufacturing the electronic device. FIG. 5 further illustrates details of how an inspection system acquires detection information related to a state of the substrate 10 in step S103. As illustrated in FIG. 5, after the first side-incident light E1 is introduced into an interior of the substrate 10 from a side of the substrate 10, the propagation of the first side-incident light E1 is affected by various features and defects on the substrate 10. FIG. 5 schematically illustrates several situations. For example, if a crack exists on the substrate 10, when the first side-incident light E1 encounters the crack, its light path will be interrupted, scattered, or refracted, forming a detectable optical feature. If minute surface morphology changes such as pimples and dimples exist on the substrate 10, even at a micrometer level, the changes will also cause a disturbance to the first side-incident light E1, for example, by generating a specific scattering pattern or a shadow effect.

For through-holes 10b that have been formed by etching, or for laser-modified regions formed after laser modification, their boundaries and internal structures have optical properties different from the surrounding substrate material. Therefore, when the first side-incident light E1 passes through or bypasses these regions, its light intensity and path will change. An enlarged view on a right side of FIG. 5 schematically illustrates how this optical change is utilized to measure an inner aperture (Wₛₘₐₗₗ) and an outer aperture (W_{large}), wherein these dimensions are important parameters for evaluating the quality of the through-holes or the modified regions. Similar to the principle of FIG. 4, a portion of the light may be scattered above the substrate 10 by these defects or features and be captured by a photosensitive element of a lens 12. By analyzing these optical changes, a processing unit 70 (as illustrated in FIG. 6 to FIG. 8, not shown in FIG. 5) can identify and locate defects such as cracks, pimples, and dimples, and can also measure key dimensions of the through-hole regions to determine whether the key dimensions conform to process specifications. Furthermore, the inspection method described in the embodiment can not only evaluate the dimensions of a single through-hole region, but can also be used for measuring a pitch between a plurality of adjacent through-hole regions. Through an overall image acquired by the first side-incident light E1 and the lens 12, which may include a plurality of feature points, the processing unit can identify the respective center positions or edge contours of a plurality of through-hole regions 10b (or laser-modified regions 10a). Next, based on these located feature points, the processing unit can calculate a relative distance therebetween to accurately acquire a pitch value between the feature points, and compare this measured value with a preset design standard to determine whether the pitch conforms to the specifications.

FIG. 6 is a block diagram of an optical inspection system 100 according to a first embodiment of the present disclosure. As illustrated in FIG. 6, the optical inspection system 100 includes at least one first light source 11, disposed at a side of a substrate 10. It should be understood that in the present disclosure, the substrate 10 can be regarded as a specific example of a “transparent object to be measured”. Therefore, the measurement of the substrate 10 by the optical inspection system 100 can be generally referred to as the measurement of any transparent object to be measured that meets specific conditions. In an embodiment, the “transparent object to be measured” can be defined as a material that is a medium having a white light transmittance of greater than 75%. For the convenience of subsequent description, the following embodiments will continue to describe the substrate 10 as a representative transparent object to be measured.

In the present embodiment, the first light source 11 can be a light-emitting diode (LED) light bar. The LED light bar can include a plurality of light-emitting diodes of different colors, for example, red, green, and blue light-emitting diodes. By adjusting an intensity ratio of each color of the light-emitting diodes, light source color mixing can be performed to generate the first side-incident light E1 with an optimal transmittance or contrast according to material properties of the substrate 10 or a defect type to be detected. A wavelength of the first side-incident light E1 generated by the first light source 11 is selectable, for example, the wavelength range of the first side-incident light E1 can be from 360 nanometers to 830 nanometers. Furthermore, a height of the first light source 11 along a normal direction of the substrate 10 (a Z direction, as illustrated in FIG. 6) is adjustable, for example, the height can be fine-tuned within a range of 0 to 2 millimeters to optimize an angle and a position of the light introduced into the substrate 10. To ensure inspection stability and to avoid direct contact between the substrate 10 and a fixture, a height of an exposed edge of the fixture carrying the substrate 10 is at least greater than 1 centimeter. Furthermore, as illustrated in FIG. 6, the optical inspection system 100 can also optionally include a second light source 111, providing illumination from another side of the substrate 10 to achieve a more comprehensive inspection.

The optical inspection system 100 can further include a lens 12 and a camera 30 (which includes a photosensitive element), located above the substrate 10 or at another suitable light-receiving position. The lens 12 is for collecting an output light E2 exiting or reflected from an interior or a surface of the substrate 10, and for forming an image. The optical inspection system 100 further includes a processing unit 70 and a memory 80. The processing unit 70 is coupled to the camera 30 and the memory 80. In operation, after the first side-incident light E1 generated by the first light source 11 is introduced into the interior of the substrate 10, the first side-incident light E1 interacts with a laser-modified region 10a or possibly existing defects inside the substrate 10. In the present disclosure, the side-incident light is perpendicular to the Z direction. Because a refractive index of the laser-modified region or a defect is different from a refractive index of a body of the substrate 10, or because of scattering or absorption of light caused by the defect, an identifiable change in optical properties (such as intensity, distribution pattern) of the output light E2 will be resulted. Therefore, after the photosensitive element captures the image formed by the output light E2, detection information represented by the image can be transmitted to the processing unit 70. The processing unit 70 can then execute a rule base or an artificial intelligence algorithm stored in the memory 80 to analyze the detection information, thereby determining a quality of the laser-modified region 10a or whether an abnormality exists in the substrate 10, that is, determining whether the laser modification passes an inspection.

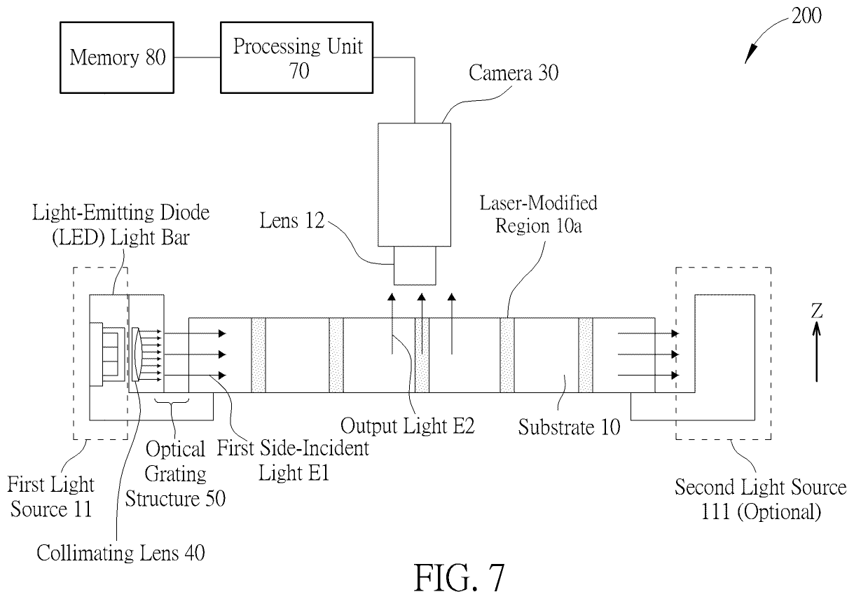

FIG. 7 is a block diagram of an optical inspection system 200 according to a second embodiment of the present disclosure. As illustrated in FIG. 7, the optical inspection system 200 also includes at least one first light source 11. In the present embodiment, the first light source 11 can be a light-emitting diode (LED) light bar, having characteristics as in the embodiment of FIG. 6 described above. For example, the LED light bar can include a plurality of light-emitting diodes of different colors, such as red, green, and blue, and by adjusting an intensity ratio of each color of the light-emitting diodes, light source color mixing can be performed to generate the first side-incident light E1 that is optimized according to material properties of the substrate 10 or a defect type to be detected. A wavelength of the first side-incident light E1 is also selectable, for example, the wavelength range can be from 360 nanometers to 830 nanometers.

Different from the optical inspection system 100, the optical inspection system 200 has a collimating lens 40 and an optical grating structure 50 disposed in sequence according to a light path between the first light source 11 and the substrate 10. The collimating lens 40 is for collimating light emitted from the first light source 11, to make the light become a parallel light or a light beam with a specific divergence angle, ensuring that the light irradiating a side edge of the substrate 10 is more uniform and consistent. The optical grating structure 50 after the collimating lens 40 is for further adjusting or shaping a light pattern or a spot characteristic of the first side-incident light E1. For example, the optical grating structure 50 can generate a dot-shaped spot (circular), a one-dimensional line-shaped spot, or a two-dimensional area-shaped spot. This is beneficial for the detection of specific types of defects or for improving the efficiency of scanning inspection. The optical inspection system 200 also includes a lens 12, a camera 30 (which includes a photosensitive element), a processing unit 70, and a memory 80. The functions of these components are similar to those in the optical inspection system 100 of the embodiment of FIG. 6, and are used for capturing an output light E2, forming an image, and performing an AI algorithm analysis and determination. Similarly, a height of the first light source 11 (the LED light bar) along a normal direction of the substrate 10 (a Z direction, as illustrated in FIG. 7) is adjustable, for example, the height can be fine-tuned within a range of 0 to 2 millimeters to optimize an angle and a position of the light introduced into the substrate 10. To ensure inspection stability and to avoid direct contact between the substrate 10 and a fixture, a height of an exposed edge of the fixture carrying the substrate 10 is at least greater than 1 centimeter. Furthermore, as illustrated in FIG. 7, the optical inspection system 200 can also optionally include a second light source 111, providing illumination from another side of the substrate 10 to achieve a more comprehensive inspection.

To perform a comprehensive inspection on the entire substrate 10 or on a plurality of laser-modified regions 10a thereon, the optical inspection system 200 can be configured with a scanning mechanism. For example, in some embodiments, if a light spot formed by optical components such as the optical grating structure 50 is dot-shaped (circular), the first light source 11 (and its associated optical components, such as the collimating lens 40 and the optical grating structure 50) can be designed to perform a moving scan along one direction of the substrate 10 (e.g., a Y-axis direction), while the camera 30 and its lens 12 perform a synchronous moving scan along another orthogonal direction of the substrate 10 (e.g., an X-axis direction). Alternatively, the light source and the camera can be fixed, and the substrate 10 can be carried by a moving platform to perform a two-dimensional scan in an X-Y plane. In this way, all target regions on the substrate 10 can be sequentially inspected, and detection information of each region can be transmitted to the processing unit to generate an overall inspection map. The detection principle of FIG. 7, which utilizes the shaped first side-incident light E1 to interact with internal structures and defects of the substrate to generate the analyzable output light E2, is similar to the aforementioned embodiment, and thus the details will not be repeated here.

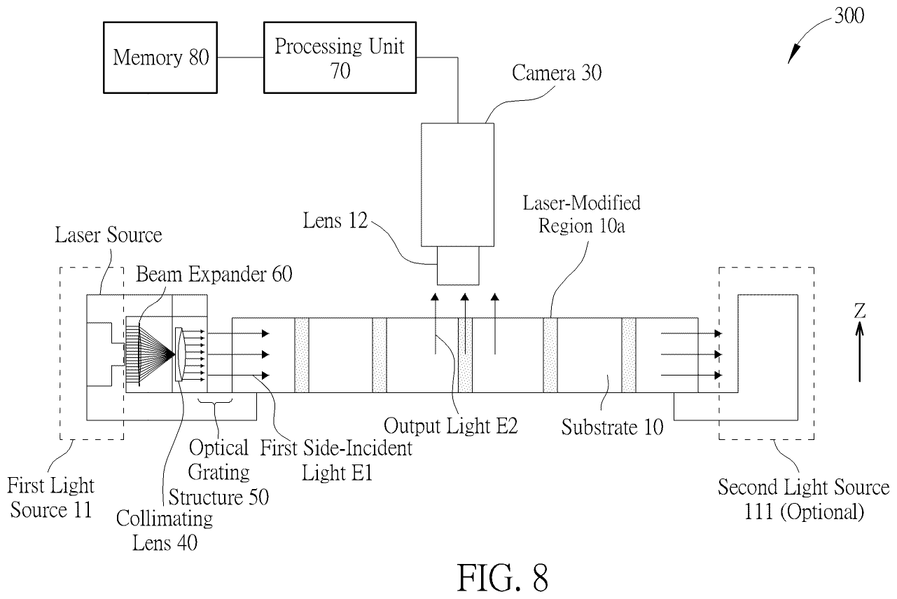

FIG. 8 is a block diagram of an optical inspection system 300 according to a third embodiment of the present disclosure. As illustrated in FIG. 8, the optical inspection system 300 includes at least one first light source 11, which is a laser source in the present embodiment. Compared to a light-emitting diode light bar, a laser source can provide a light beam with a higher intensity, a better directionality, and a better monochromaticity. A wavelength of the first side-incident light E1 generated by the laser source is also selectable, for example, the wavelength range can be from 360 nanometers to 830 nanometers to adapt to characteristics of different materials of the substrate 10 and inspection requirements. Similar to the aforementioned embodiments, a height of the first light source 11 along a normal direction (a Z direction) of the substrate 10 can also be adjusted, for example, within a range of 0 to 2 millimeters to optimize a light introduction angle. Furthermore, a height of an exposed edge of a fixture carrying the substrate 10 is at least greater than 1 centimeter to avoid unnecessary contact. Furthermore, as illustrated in FIG. 8, the optical inspection system 300 can also optionally include a second light source 111, providing illumination from another side of the substrate 10 to achieve a more comprehensive inspection.

In the optical inspection system 300, optical components including a beam expander 60, a collimating lens 40, and an optical grating structure 50 are disposed in sequence according to a light path between the first light source 11 (the laser source) and the substrate 10. First, the beam expander 60 is for expanding an original laser beam emitted from the laser source 11, adjusting the original laser beam to a beam diameter suitable for subsequent optical component processing or for meeting a specific illumination area requirement. Next, the expanded beam enters the collimating lens 40 and is collimated into a parallel beam with a minimal divergence angle to ensure uniformity for long-distance propagation or for a subsequent action of the optical grating. Finally, the collimated laser beam passes through the optical grating structure 50. The optical grating structure 50 modulates a wavefront of the beam to generate the first side-incident light E1 having a specific spot characteristic. For example, the beam can be shaped into an extremely fine line-shaped spot or a dot-shaped spot to facilitate high-resolution scanning, or formed into a specific two-dimensional rectangular pattern to enhance sensitivity to certain morphologies or defects.

The optical inspection system 300 also includes a lens 12, a camera 30 (which includes a photosensitive element), a processing unit 70, and a memory 80. The functions of these components are similar to those in the aforementioned embodiments (e.g., FIG. 6, FIG. 7), and are used for capturing an output light E2 after interaction within the substrate 10, for forming an image, and for performing an artificial intelligence algorithm analysis and determination.

Similarly, to perform a comprehensive inspection on the entire substrate 10 or on a plurality of laser-modified regions 10a thereon, the optical inspection system 300 can also be configured with a scanning mechanism. For example, if a light spot formed by a light source system (including the beam expander 60, the collimating lens 40, and the optical grating structure 50) is dot-shaped (circular), the first light source 11 (and its series-connected optical components) can be designed to perform a moving scan along one direction of the substrate 10 (e.g., a Y-axis direction), while the camera 30 and its lens 12 perform a synchronous moving scan along another orthogonal direction of the substrate 10 (e.g., an X-axis direction) to scan all of the laser-modified regions 10a row by row. Alternatively, a fixed light source and a fixed camera can be adopted, and the substrate 10 can be carried by a moving platform to perform a two-dimensional scan in an X-Y plane. The collected detection information of each region is then integrated by the processing unit to generate an overall inspection map. The basic principle of the inspection, which utilizes the precisely shaped first side-incident light E1, is similar to the aforementioned embodiments. The detection principle of FIG. 8, which utilizes the shaped first side-incident light E1 to interact with internal structures and defects of the substrate to generate an analyzable output light E2, is similar to the aforementioned embodiments, and thus the details will not be repeated here.

In the various embodiments described above, such as those illustrated in FIG. 6 to FIG. 8, the lens 12 paired with the camera 30 itself defines a specific Field of View (FOV). The FOV refers to an actual area range that the lens 12 can clearly image at a specific working distance, and a size of the FOV determines an area of the substrate 10 that can be observed in a single image capture. In practical applications, the size of the FOV is designed according to a required resolution, an optical magnification of the lens, and a size of the photosensitive element. Since an area of the substrate 10 to be inspected or a total range of a plurality of laser-modified regions 10a distributed thereon is usually larger than the FOV range that the lens 12 can capture in a single instance, the aforementioned scanning mechanism (e.g., moving the substrate 10, or synchronously moving the first light source 11 and the camera 30) utilizes the FOV as a basic imaging unit. The lens 12 can, in a region-by-region manner, progressively and continuously move a relative position of the FOV to sequentially capture a plurality of partial images of the entire target surface. These sequentially acquired regional images are then transmitted to the processing unit 70 for individual analysis, defect identification, or further stitching and integration, thereby achieving a comprehensive inspection of a large-area substrate and the generation of an overall inspection map. In another embodiment for implementing region-by-region scanning, if the first side-incident light E1 generated by the first light source 11 and possibly configured optical components (e.g., FIG. 7 or FIG. 8) forms a line-shaped spot on or inside the substrate 10, a more efficient scanning strategy can be adopted. In this situation, the line-shaped spot is usually designed to extend along one dimension of the substrate 10 (e.g., a Y-axis direction, that is, across a width or a portion of the width of the substrate) and provide illumination. In this way, it is only necessary for the lens 12 to move along a single axis in another dimension that is substantially perpendicular to the extending direction of the line-shaped spot (e.g., an X-axis direction), to be able to scan and capture images of the regions of the substrate illuminated by or interacting with the line-shaped spot, one region at a time. This scanning method can acquire a wider band of regional information with each movement of the lens, thereby effectively improving the inspection speed and efficiency for large-area substrates.

In other embodiments, the optical inspection system can also be configured with a plurality of cameras. The cameras can be arranged, for example, in a one-dimensional array along a direction perpendicular to a main scanning direction of the substrate, or in a two-dimensional array to cover a larger inspection area. By using a plurality of cameras, the optical inspection system can simultaneously capture a wider or more angular range of images of the substrate regions in a single scanning path (if moving) or in a single exposure (if for static large-area inspection). Thus, an overall inspection throughput and coverage of the substrate can be effectively improved without significantly increasing the overall scanning time, and in some cases, even while reducing the requirement for the moving speed of a single scanning axis.

The optical inspection systems 100 to 300 of the present disclosure (as illustrated in FIG. 6 to FIG. 8) and the corresponding inspection methods are not only capable of detecting the aforementioned scratches, cracks, dimensions, and contours, but also have the characteristic of evaluating a surface roughness of the substrate 10. Examples of measurable roughness parameters and their detection ranges can include: an arithmetic average roughness of about 0.01 micrometers (μm) to 0.5 micrometers, or a mean roughness of a plurality of points. These parameters can be used as indicators to characterize changes in the micro-profile of the surface of the substrate 10. The detection principle of the surface roughness can also utilize the interaction of the side-incident light with the surface of the substrate 10. When the first side-incident light E1 (or a second side-incident light) irradiates the surface of the substrate 10, the microscopic unevenness of the surface (i.e., the roughness) will cause scattering of the incident light to varying degrees and at various angles. Generally, a rougher surface will cause the light to scatter in a wider range of directions, and an intensity distribution of the scattered light will also be more diffuse. A smoother surface, on the other hand, mainly produces specular reflection or scattering that is more concentrated in direction. The lens 12 and the camera 30 (which includes the photosensitive element) are responsible for collecting the scattered light or reflected light modulated by the surface roughness and for forming an image. Subsequently, the processing unit 70 can back-calculate and quantify the surface roughness value by analyzing a spatial distribution of light intensity in the image, a degree of expansion of a light spot, a light intensity at a specific scattering angle, or by using more complex image texture analysis, artificial intelligence algorithms, or the like. It should be understood that in one embodiment, the optical inspection system can finally present the analyzed roughness information in a visualized manner. For example, a roughness distribution map can be generated, wherein different colors or grayscale levels directly correspond to different measured roughness values or roughness grades. Generating the roughness distribution map enables an operator or an automated system to intuitively understand the overall condition, uniformity, and spatial distribution of the surface roughness of the substrate in specific areas.

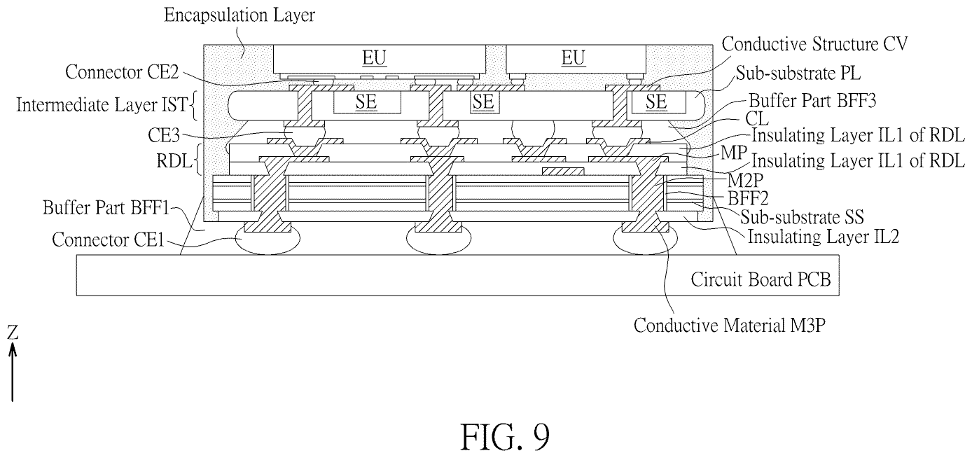

FIG. 9 is a structural diagram of an electronic device according to an embodiment of the present disclosure. Referring to FIG. 9, FIG. 9 is a schematic cross-sectional diagram of the structure of the electronic device. The structure can be an electronic package, which can be provided, for example, through a wafer-level package (WLP) process, a panel-level package (PLP) process, a System-in-Package (SiP), or other similar multilayer heterogeneous integration modules. The structure can be a chip-first process or a chip-last/RDL-first process, and a plurality of components are integrated therein to achieve specific electronic functions. As illustrated in FIG. 9, an overall structure of the electronic device can be constructed by stacking from a bottom upwards. A bottommost layer can be a circuit board, such as a Printed Circuit Board, which provides a mechanical support foundation for the entire device and is provided with circuits for external connection. The electronic device can be electrically and mechanically connected to the circuit board PCB through connectors CE1 at the bottom, such as a Solder Ball Grid Array (BGA) or other Surface Mount Technology (SMT) contacts. A buffer part BFF1 can cover the connectors CE1. The buffer part BFF1 can be an insulating material, composed of an elastic material or a specific structure, for absorbing mechanical stress or thermal stress to protect a solder joint reliability of the connectors CE1. A structure extending upward from the connectors CE1 can include a multilayer sub-substrate SS. A conductive material M3P and an insulating layer IL2 for interlayer isolation can be disposed on the sub-substrate SS.

The electronic device further includes a sub-substrate PL. A Redistribution Layer (RDL) can be disposed below (or surrounding) the sub-substrate PL. A main function of the RDL is to reroute fine-pitch contacts of upper active and passive components to wider-pitch contacts on the sub-substrate PL or the sub-substrate SS, to achieve high-density interconnection. The RDL can be formed by stacking a plurality of layers of conductive materials, such as a conductive material MP and a conductive material M2P, and a plurality of layers of insulating materials, such as an insulating layer IL and an insulating layer IL1, in an alternating manner. A conductive material CL and a conductive material CV illustrated in FIG. 9 can serve as vertical electrical connections between these different conductive layers, for example, as a filling material in a via or to form a pillar. To further protect the structure, the electronic device can also be configured with other buffer parts. For example, a buffer part BFF2 can surround a through-hole edge of the multilayer sub-substrate SS to protect the through-hole. A buffer part BFF3 can be located between the sub-substrate PL and the RDL to cover connectors CE3. A plurality of active components and/or passive components (collectively referred to as active and passive components EU, SE) can be mounted on or embedded in the sub-substrate PL. For example, the active component EU can be an Integrated Circuit (IC) chip, and the passive component SE can be a resistor, a capacitor, an inductor, or the like. These active and passive components EU, SE can be electrically connected to the RDL or other circuit layers below through the connectors CE3. In addition, an intermediate layer IST can be disposed on or around the sub-substrate PL and the active/passive components SE. An upper portion of the intermediate layer IST may also include connectors CE2 for connecting to other modules, test points, or as part of the package. Furthermore, in the electronic device, an outermost layer can be an encapsulation layer, for sealing and protecting all internal electronic components from an external environment (such as moisture, dust, mechanical damage).

It should be understood that the sub-substrate PL and the multilayer sub-substrate SS of the electronic device can be applied to the manufacturing method of a through glass via and the optical inspection method mentioned in the foregoing embodiments. For example, the sub-substrate PL and the multilayer sub-substrate SS themselves can serve as the target substrate 10 for performing the “first modification step” (as in step S102 and FIG. 2). For example, a plurality of laser-modified regions 10a can be formed on the sub-substrate PL and the multilayer sub-substrate SS by using a laser to prepare for subsequent etching to form through glass vias. After the laser modification is completed and before etching, the optical inspection system (100, 200, or 300) and method as disclosed in step S103 and FIG. 4 to FIG. 8 can be used to inspect the laser-modified regions 10a on the sub-substrate PL and the multilayer sub-substrate SS. In other words, the manufacturing and inspection method of the foregoing embodiments can be effectively applied to the processing and quality control process of an internal substrate (such as the sub-substrate PL and the multilayer sub-substrate SS) in the electronic device as illustrated in FIG. 9.

In FIG. 9, an edge of the sub-substrate PL can be designed to be arc-shaped or curved. Compared to a conventional right-angled or sharp corner, adopting such an arc-shaped or curved edge design has the following advantages. First, the arc-shaped or curved edge design can reduce stress concentration. A sharp corner is prone to becoming a point of stress concentration, and is liable to generate cracks, especially when subjected to thermal expansion and contraction caused by temperature changes or external mechanical stress. The arc-shaped edge allows stress to be distributed more uniformly, thereby significantly reducing the risk of crack generation or fracture at the edge of the sub-substrate PL (especially when the sub-substrate PL is a brittle material such as glass). Second, the arc-shaped or curved edge design can improve packaging reliability. By reducing potential crack initiation points and stress failure points, the arc-shaped or curved edge design can improve the mechanical strength, fatigue resistance, and long-term reliability of the entire electronic device. Third, the arc-shaped or curved edge design can improve a molding process yield. When performing injection molding or other over-molding processes, the arc-shaped or curved edge helps a molding material (such as an epoxy resin) to flow more smoothly, reducing the chances of generating defects such as bubbles, voids, or uneven filling, thereby improving the quality and yield of the packaging. Therefore, in the embodiment of FIG. 9, the arc-shaped or curved edge design of the sub-substrate PL can improve the structural stability, durability, and process yield of the electronic device, and is particularly suitable for high-end packaging applications with higher reliability requirements or greater process stress. According to some embodiments, the electronic device referred to in the present disclosure can include a Chip on Wafer on Substrate (CoWoS) package structure, a System on a Chip (SoC), a System in a Package (SiP), an antenna in package (AiP), a Co-packaged Optics (CPO), or various combinations of the above devices, but is not limited thereto.

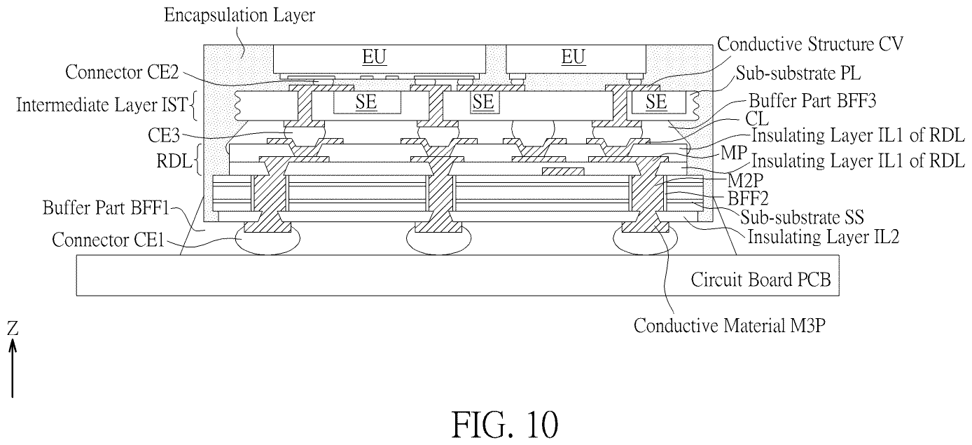

FIG. 10 is a structural diagram of an electronic device according to another embodiment of the present disclosure. Referring to FIG. 10, FIG. 10 is a schematic cross-sectional diagram of the structure of the electronic device according to another embodiment of the present disclosure. An overall architecture, main components, and basic functions of the electronic device described in FIG. 10 are similar in many aspects to the electronic device illustrated in the foregoing FIG. 9. For the sake of brevity in the description, a detailed structure and connection relationships of these components that are the same as or functionally correspond to those in the embodiment of FIG. 9 will not be repeated here, and reference can be made to the foregoing description for FIG. 9. The most primary distinguishing feature between the electronic device illustrated in FIG. 10 and the foregoing embodiment lies in an edge design of the sub-substrate PL. In the electronic device of FIG. 10, the edge of the sub-substrate PL is designed to be a wavy shape or an undulating/uneven shape. This edge contour is a non-linear geometric feature with undulations, replacing a traditional straight-cut edge or the simple arc-shaped/curved edge as described in the embodiment of FIG. 9. It should be understood that the technical advantages brought by adopting the wavy or undulating design for the edge of the sub-substrate PL are similar to the advantages of the arc-shaped edge in the embodiment of FIG. 9, and may provide further enhancement in some aspects. In an embodiment, adopting the wavy or undulating design for the edge provides superior stress dispersion and reduction. The wavy or undulating edge contour, due to its geometric discontinuity and multiple curvature variations, can more effectively interrupt a stress propagation path than a simple arc, and can more uniformly disperse concentrated stress generated during a manufacturing process (such as substrate dicing, package molding) or subsequent use (such as temperature cycling, mechanical loading) to a wider edge region. This design can create more stress relief points or change a pattern of stress concentration, thereby more significantly reducing an initial probability and an extension tendency of micro-crack generation at the edge of the sub-substrate PL (especially for brittle materials such as glass). Furthermore, adopting the wavy or undulating design for the edge can improve crack propagation resistance. Even under extreme stress conditions, if an initial micro-crack unfortunately occurs at the edge of the sub-substrate PL, the wavy or undulating surface contour can also make a propagation path of the crack more tortuous and irregular. This increases fracture energy required for crack propagation and may cause the crack to turn or terminate during propagation, thereby inhibiting or effectively delaying the overall crack propagation, and further improving the durability of the device and its reliability in harsh environments. Therefore, in the embodiment of FIG. 10, the wavy or undulating edge design of the sub-substrate PL can also improve the structural stability, durability, and process yield of the electronic device, and is particularly suitable for application scenarios with extremely high requirements for mechanical reliability, impact resistance, or long-term lifespan.

In summary, the embodiments disclose a method for manufacturing an electronic device and an optical inspection system. The optical inspection system utilizes a side-incident light technology, combined with an artificial intelligence algorithm, to perform real-time internal and surface inspection on a substrate after a first laser modification step and before etching. The optical inspection system can include a specific light source (such as a light-emitting diode light bar or a laser source), optical shaping components (such as a collimating lens, a beam expander, an optical grating structure), a lens, and a processing unit, etc. The optical inspection system can be combined with various light spot illuminations or multi-camera configurations, enabling the optical inspection system to effectively cope with and complete the comprehensive inspection requirements of large-sized substrates, achieving efficient and precise inspection. Furthermore, the arc-shaped, wavy, or undulating edge design of a sub-substrate in the electronic device helps to reduce stress concentration and enhance structural reliability. Moreover, the optical inspection system can accurately identify a plurality of features such as scratches, cracks, surface roughness, and key dimensions, and based on the features, determine whether a rework is needed and adjust process parameters, effectively overcoming the shortcomings of prior top-view inspection, and can therefore greatly improve production yield and overall efficiency.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method for manufacturing an electronic device, comprising:
providing a substrate;
performing a first modification step on at least a portion of the substrate;
generating a first side-incident light to introduce the first side-incident light into an interior of the substrate;
inspecting the substrate after the first modification step to acquire detection information related to a state of the substrate; and
determining whether a rework process is required for the substrate based on the detection information.

2. The method of claim 1, further comprising:
when the rework process is determined to be required for the substrate, performing a laser re-modification step on the substrate.

3. The method of claim 2, wherein the first modification step is performed utilizing a first laser condition, the laser re-modification step is performed utilizing a second laser condition, and the second laser condition is different from the first laser condition.

4. The method of claim 1, wherein a wavelength range of the first side-incident light is from 360 nanometers to 830 nanometers.

5. The method of claim 1, further comprising:
when it is determined that the rework process is not required for the substrate, performing an etching step on the substrate to form at least one through-hole in the substrate.

6. The method of claim 1, further comprising:
generating a second side-incident light incident from another side of the substrate to introduce the second side-incident light into the interior of the substrate.

7. The method of claim 1, further comprising:
adjusting a light pattern of the first side-incident light by utilizing an optical grating structure.

8. The method of claim 1, wherein the step of inspecting the substrate is performed sequentially on a plurality of regions of the substrate, and the method further comprises:
integrating the detection information acquired for the plurality of regions to generate an overall inspection map of the substrate.

9. The method of claim 1, wherein the first side-incident light is generated by a light-emitting diode (LED) light bar, and a collimating lens is disposed between the LED light bar and the substrate, and configured to collimate the first side-incident light.

10. The method of claim 1, wherein the first side-incident light is generated by a laser source, and a beam expander and a collimating lens are disposed between the laser source and the substrate, and configured to enhance an extension property of the first side-incident light.

11. An optical inspection system, comprising:
an object to be measured;
a first light source disposed at a side of the object to be measured, and configured to provide a first side-incident light; and
a lens disposed above the object to be measured;
wherein after a first modification step is performed on at least a portion of the object to be measured, the first light source generates the first side-incident light to introduce the first side-incident light into an interior of the object to be measured, the lens inspects an image of the object to be measured after the first modification step, wherein the image is formed on a photosensitive element, to acquire detection information related to a state of the object to be measured, and the detection information is used for determining whether a rework process is required for the object to be measured.

12. The system of claim 11, further comprising:
a memory configured to store at least one reference laser pattern data; and
a processing unit coupled to the lens and the memory;
wherein the processing unit is configured to receive the detection information and execute an artificial intelligence (AI) algorithm to compare the detection information with the at least one reference laser pattern data, and to determine whether the rework process is required for the object to be measured accordingly.

13. The system of claim 12, wherein when the rework process is required for the object to be measured, the object to be measured undergoes a laser re-modification step, the first modification step is performed utilizing a first laser condition, the laser re-modification step is performed utilizing a second laser condition, and the second laser condition is different from the first laser condition.

14. The system of claim 12, wherein the lens is configured to sequentially inspect a plurality of regions of the object to be measured, and the processing unit is configured to integrate the detection information acquired for the plurality of regions to generate an overall inspection map of the object to be measured.

15. The system of claim 12, wherein the processing unit is configured to determine based on the detection information, whether at least one scratch exists on the object to be measured, whether at least one crack exists on the object to be measured, evaluate a surface roughness of the object to be measured, and measure a pitch between two adjacent through-hole regions after the first modification step, and determine whether the pitch conforms to a preset standard.

16. The system of claim 11, wherein a wavelength range of the first side-incident light provided by the first light source is from 360 nanometers to 830 nanometers.

17. The system of claim 11, further comprising:
a second light source disposed at another side of the object to be measured, configured to provide a second side-incident light to be introduced into the interior of the object to be measured;
wherein the lens is further configured to inspect an image of the second side-incident light formed on the photosensitive element.

18. The system of claim 11, further comprising:
an optical grating structure disposed between the first light source and the object to be measured, and configured to adjust a light pattern of the first side-incident light.

19. The system of claim 11, further comprising:
a collimating lens disposed between the first light source and the object to be measured, and configured to collimate the first side-incident light;
wherein the first light source is a light-emitting diode (LED) light bar.

20. The system of claim 11, further comprising:
a collimating lens disposed between the first light source and the object to be measured; and
a beam expander disposed between the collimating lens and the first light source;
wherein the first light source is a laser source.
